(19) United States
(12) Patent Application Publication
(10) Pub. No.: US 2009/0242017 A1
(43) Pub. Date: Oct. 1, 2009

(54) DYE-SENSITIZED SOLAR CELL

(75) Inventor: Ryosuke YASUDA, Shizuoka-shi (JP)

Correspondence Address: SUGHRUE-265550, 2100 PENNSYLVANIA AVE. NW, WASHINGTON, DC, 20037-3213, US

(73) Assignee: KOITO MANUFACTURING CO., LTD., Tokyo (JP)

(21) Appl. No.: 12/414,293

(22) Filed: Mar. 30, 2009

(30) Foreign Application Priority Data
Mar. 31, 2008 (JP) 2008-089957

(51) Int. Cl. H01L 31/02

(52) U.S. Cl. 136/252; 257/E31.11

(57) ABSTRACT

A dye-sensitized solar cell is provided. The solar cell includes a first electrode substrate including a first tabular substrate which is transparent; a transparent conductive film; and an oxide semiconductor layer impregnated with a sensitizing dye; a second electrode substrate including a second tabular substrate; a conductive film; and a catalyst conductive layer; and a sealing member which seals a peripheral area between the first electrode substrate and the second electrode substrate. The sealing member includes a sealant in a first area of the peripheral area that overlaps with the transparent conductive film or the conductive film; and a sealing base material in a second area of the peripheral area that does not overlap with the transparent conductive film or the conductive film. An electrolyte is scaled in a sealing space formed by the first and second electrodes and the sealing member.

This application claims priority from Japanese Patent Application No, 2008-0 89957, filed on Mar. 31, 2008, the entire contents of which are hereby incorporated by reference.

### BACKGROUND OF THE INVENTION

1. Technical Field

Apparatuses and devices consistent with the present disclosure relate to solar cells and, more particularly, to dye-sensitized solar cells.

2. Related Art

JP-A-2006-185646 describes a related art dye-sensitized solar cell which is configured such that a first tabular transparent base material formed as a window electrode. The first tabular transparent base material is formed by laminating a transparent conductive film and an oxide semiconductor layer which absorbs a sensitizing dye, and acts as a first electrode. A second tabular base material is formed by laminating a conductive film and a catalyst conductive layer, and acts as a counter electrode. The first and second tabular base materials are disposed to face each other such that the oxide semiconductor layer opposes the catalyst conductive layer. An electrolyte is introduced into a space between the first and second tabular base materials, and a peripheral portion of the first and second tabular materials is tightly sealed using a sealant, such that the electrolyte is sealed within a sealed space between the first and second tabular base materials.

However, in the related art, in order to prevent the electrolyte (including one which is gasified) from leaking out through adhesive interfaces between the sealant and the tabular base materials, there is a disadvantage in that it is necessary to increase a loading width (a width of a sealing portion) of the sealing adhesive to some degree. As the loading width is increased, an effective power generating area of the solar cell decreases.

Further, the related art solar cell is practically provided as a solar power panel in which a number of rectangular solar cells are lengthwise and crosswise disposed close to one another in a grid shape. However, since the sealing portion of each cell protrudes to the outside of the tabular base material, there is a disadvantage in that adjacent cells must be separated from each other by an amount corresponding to the amount the sealing portion protrudes outside of the tabular base material. For this reason, the number of cells which can be disposed in a given panel area is decreased, preventing a total electric generating capacity of the solar cell panel from being improved.

It has been proposed by the present inventor to use a laser welding process in place of the sealant order to attempt to address some of the above disadvantages. In the laser welding process, the first and second tabular base materials are interposed, and the peripheral portion between the first and second tabular base materials is melted by irradiating laser light on the sealing portion from above the transparent base material in order to weld the first tabular base material and the second tabular base material together to create a seal. It was thought that the laser welding portion would protrude less to the outside of the first and second tabular base materials than in the case of the sealant.

However, even though the laser welding process appeared to help to prevent the electrolyte from leaking out and to reduce the amount that the laser welding portion protrude to the outside of the base material, there was created a disadvantage in that, when the laser welding is performed on the first and second tabular base materials, a part of the conductive film, which serves as a power feeding path and which is formed on the peripheral portion of the base materials, is damaged by irradiation of the laser light. Thus, a function of the conductive film is damaged, for example by disconnection.

### SUMMARY OF THE INVENTION

Exemplary embodiments of the present invention address the foregoing disadvantages and other disadvantages not described above. However, the exemplary embodiments of the present invention are not required to overcome the disadvantages described above and, thus, some implementations of the present invention may not overcome the specific disadvantages described above.

Accordingly, it is an aspect of the invention is to provide a dye-sensitized solar cell in which the electrolyte is prevented from leaking out and which allows for an increased density of solar cells on a solar panel.

According to an illustrative aspect of the present invention, there is provided a dye-sensitized solar cell comprising a first electrode substrate, a second electrode substrate, a sealing member, and an electrolyte which is filled in a sealing space formed by the first electrode substrate, the second electrode substrate and the sealing member. The first electrode substrate comprises a first tabular substrate which is transparent; a transparent conductive film formed on the first tabular substrate; and an oxide semiconductor layer which is formed on the transparent conductive film and which is impregnated with a sensitizing dye. The second electrode substrate comprises a second tabular substrate, a conductive film formed on the second tabular substrate; and a catalyst conductive layer formed on the conductive film, the second electrode substrate being disposed to face the first electrode substrate such that the oxide semiconductor layer opposes the catalyst conductive layer. The sealing member seals a peripheral area between the first electrode substrate and the second electrode substrate, and the sealing member comprises a sealant provided at least in a first area of the peripheral area that overlaps with the transparent conductive film or the conductive film; and a sealing base material provided in a second area of the peripheral area that does not overlap with the transparent conductive film or the conductive film, the sealing base material being made of a same material as a material of the first tabular substrate or the second tabular substrate.

Other aspects and advantages of the invention will be apparent from the following description, the drawings and the claims.

### BRIEF DESCRIPTION OF THE DRAWINGS

FIG. 1 is a vertical cross-sectional view illustrating a dye-sensitized solar cell according to a first exemplary embodiment of the present invention;

FIG. 2 is a vertical cross-sectional view of the dye-sensitized solar cell taken along a line II-II shown in FIG. 1;

FIG. 3 is a vertical cross-sectional view of the dye-sensitized solar cell taken along a line III-III shown in FIG. 1;

FIG. 4 is a horizontal cross-sectional view of the dye-sensitized solar cell taken along a line IV-IV shown in FIG. 1;

FIG. 5 is an exploded perspective view of the dye-sensitized solar cell of FIG. 1;

FIG. 6 is a cross-sectional view illustrating a process of tightly sealing a sealing area of the dye-sensitized solar cell of FIG. 1 in which a conductive film in a peripheral portion of a substrate is not overlapped;

FIG. 7 is a cross-sectional view illustrating a process of tightly sealing a sealing area of the dye-sensitized solar cell of FIG. 1 in which a conductive film in a peripheral portion of a substrate is overlapped;

FIG. 8A is a vertical cross-sectional view illustrating a main portion of a dye-sensitized solar cell according to a second exemplary embodiment in which a sealing base material is formed on a part of a second substrate;

FIG. 8B is a vertical cross sectional view illustrating a portion of a dye-sensitized solar cell according to a third exemplary embodiment in which sealing base materials are formed on a part of the first and second substrates;

FIG. 9A is a vertical cross-sectional view illustrating a portion of a dye-sensitized solar cell according to a fourth exemplary embodiment in which a sealing base material is formed as a separate member from a first substrate and a second substrate;

FIG. 9B is a vertical cross-sectional view illustrating a portion of a dye-sensitized solar cell according to a fifth exemplary embodiment in which the sealing base material is formed on a part of the second substrate;

FIG. 10 is a perspective view illustrating an example of a solar power panel; and

FIG. 11 is a cross-sectional view illustrating electric wiring between solar cells in the solar power panel of FIG. 10.

### DETAILED DESCRIPTION OF EXEMPLARY EMBODIMENTS OF THE INVENTION

Hereinafter, exemplary embodiments of the invention will be described with reference to the drawings.

### First Exemplary Embodiment

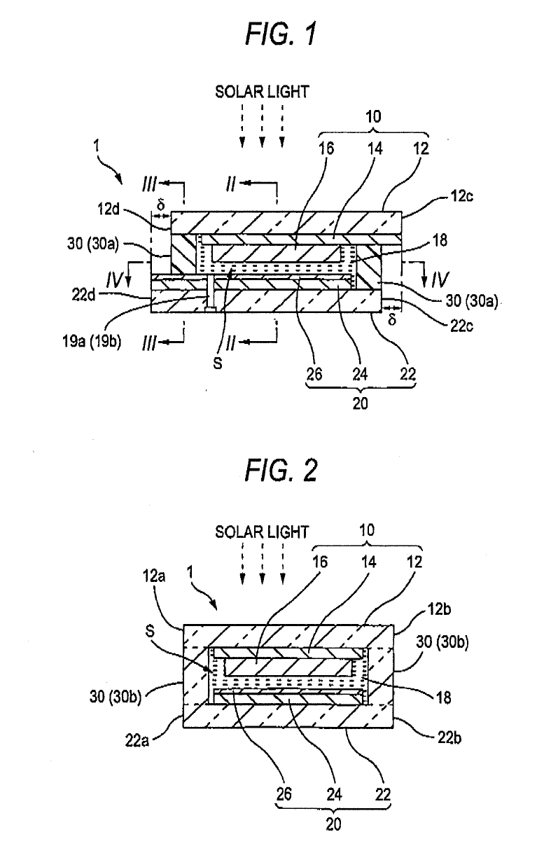

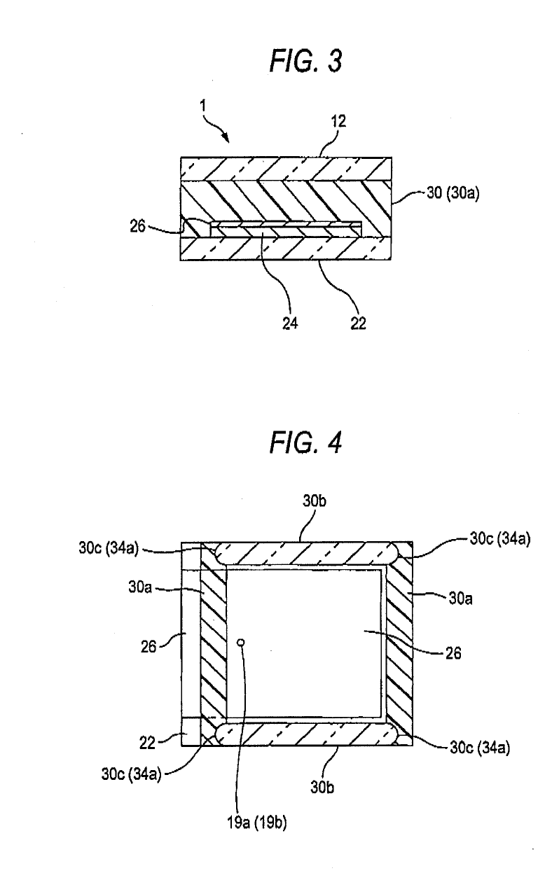

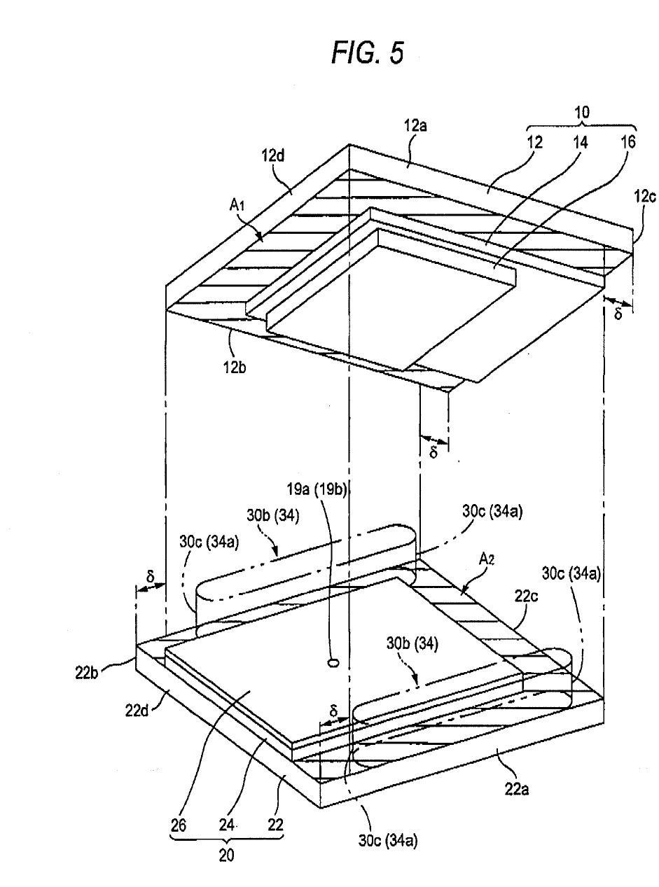

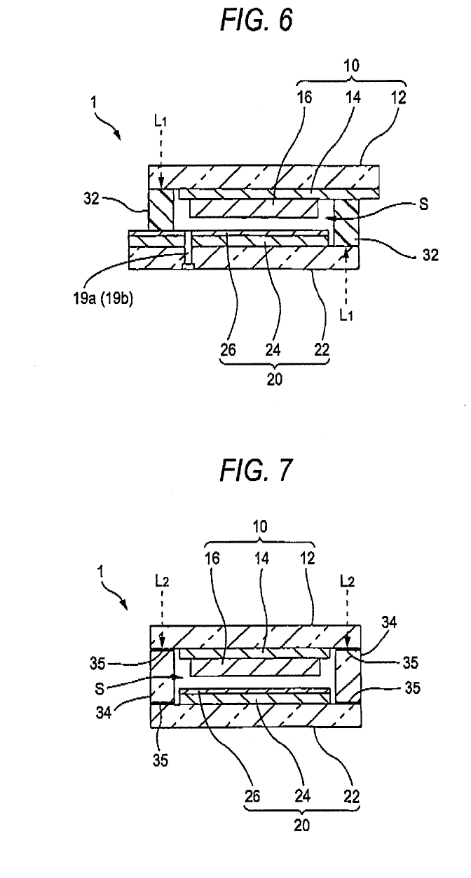

FIGS. 1 to 7 show the dye-sensitized solar cell according to a first exemplary embodiment of the invention. FIG. 1 is a vertical cross-sectional view illustrating the dye-sensitized solar cell according to the first exemplary embodiment of the invention. FIG. 2 is a vertical cross-sectional view (a cross-sectional view taken along a line II-II shown in FIG. 1) in a position perpendicular to the cross section of the solar cell shown in FIG. 1. FIG. 3 is a vertical cross-sectional view (a cross-sectional view taken along a line III-III shown in FIG. 1) in a position perpendicular to the cross section of the solar cell shown in FIG. 1. FIG. 4 is a horizontal sectional view (a cross-sectional view taken along a line IV-IV shown in FIG. 1) in a position of a sealing portion of tie solar cell. FIG. 5 is an exploded perspective view of the solar cell. FIGS. 6 and 7 are cross-sectional views illustrating a process of tightly sealing a sealing area in a peripheral portion of a substrate.

Referring to these drawings, in a dye-sensitized solar cell 1, a first electrode substrate 10 on which light is incident is integrally formed with a second electrode substrate 20 such that the first electrode substrate 10 and the second electrode substrate 20 face each other so as to be separated by a certain distance. The distance may be predetermined. The first electrode substrate 10 is formed as a first structure and is formed by laminating a transparent conductive film 14 serving as a first electrode and a porous oxide semiconductor layer 16 (hereinafter referred to as a semiconductor layer) on a surface of a first transparent glass substrate 12 that faces the second electrode substrate 20. The porous oxide semiconductor layer 16 absorbs a sensitizing dye. On the other hand, the second electrode substrate 20 is formed as a second structure and is formed by laminating a conductive metal thin film 24 serving as a second electrode and a catalyst conductive layer 26 on a surface of a second transparent glass substrate 22 that faces the first electrode substrate 10. The first electrode substrate 10 formed as the first structure and the second electrode substrate 20 formed as the second structure are then disposed to face each other such that the semiconductor layer 16 opposes the catalyst conductive layer 26. An electrolyte 18 is sealed in a sealed space S. The sealed space S is formed so as to be interposed between the first and second electrodes and is defined by tightly sealing a peripheral portion of the first electrode substrate 10 and the second electrode substrate 20 by using a sealing portion 30. An injection hole 19a for the electrolyte is also provided in the second electrode substrate 20, and a stopper 19b is inserted into the injection hole 19a to close the injection hole 19a.

The transparent conductive film 14 which is laminated on the first transparent glass substrate 12 is made of a fluoridated tin oxide (FTO) having a thickness of about 1.5 μm. The porous oxide semiconductor layer 16 formed on the transparent conductive film 14 is a porous thin film which includes oxide semiconductor particles whose average particle diameter is several nanometers to tens of nanometers, and is made of a titanium dioxide (TiO₂) having a thickness of about 15 μm. Further, in the titanium dioxide (TiO₂) formed as the semiconductor layer 16, a Ru-based dye (N719) is held as a sensitizing dye.

On the other hand, the transparent conductive film 24 which is formed on the second transparent glass substrate 22 is made of a fluoridated tin oxide (FTO) having a thickness of about 1.5 μm. The catalyst conductive layer 26 for producing electrochemical activity is formed on the transparent conductive film 24 and is made of platinum (Pt) having a thickness of about 0.5 μm.

The electrolyte 18 which is sealed in the sealed space S is made of an iodine-based electrolyte (e.g., LiI, I₂, acetonitrile, tert-butylpyridine, and dimethylpropyl imidazolium iodide), and an organic solvent including a redox pair or an ionic liquid (a room-temperature molten salt) or the like may be used.

The first and second transparent glass substrates 12 and 22 are formed as a square shape (for example, a square shape of side 10 cm) in which a length of side edge portions 12a and 12b (22a and 22b) on the right and left sides is the same as that of side edge portions 12c and 12d (22c and 22d) on the front and rear sides. In the first transparent glass substrate 12, the transparent conductive film 14 is formed as a rectangular shape in an area except a U-shaped sealing portion formation area A1 (shown as a shaded portion in FIG. 5) having a width along the side edge portions 12a and 12b on the right and left sides and the side edge portion 12d on the rear end side. The width may be predetermined. On the other hand, on the second transparent glass substrate 22, the transparent conductive film 24 and the catalyst conductive layer 26 are formed as a rectangular shape in an area except a U-shaped sealing portion formation area A2 (shown as a shaded portion in FIG. 5) having a width along the side edge portions 22a and 22b on the right and left sides and the side edge portion 12c on the front end side. The width may be predetermined

As shown in FIG. 5, the side edge portions 12a and 12b (22a and 22b) on the right and left sides correspond with each other, and the side edge portions 12c and 12d (22c and 22d) on the front and rear sides are disposed to face each other with an offset by an amount δ (for example, 3.0 mm) in a backward or forward direction (horizontal direction in FIGS. 1 and 4). The amount δ may be predetermined.

The sealing portion 30 is provided so as to be extended in a strip shape along the U-shaped sealing portion formation areas A1 and A2 which face each other, and thus the sealing portion 30 surrounds the porous oxide semiconductor layer 16 and the catalyst conductive layer 26 which oppose each other. Further, the sealing portion 30 and the conductive films 14 and 24 are separated by a slight amount.

The sealing portion 30 is made of a sealant sealing portion 30a and a laser sealing portion 30b. The sealant sealing portion 30a has a width of about 1.0 mm. The sealant sealing portion 30a is made of an ultraviolet cure sealant for tightly sealing the side edge portions 12c and 12d (22c and 22d) on the front and rear sides of the first and second transparent glass substrates 12 and 22. The laser sealing portion 30b, for example, has a width of 0.5 mm and is made of a glass welding portion for tightly sealing the side edge portions 12a and 12b (22a and 22b) on the right and left sides of the first and second transparent glass substrates 12 and 22.

That is, the sealant sealing portion 30a is generated as follows. Ultraviolet cure sealants 32 suitable for bonding glasses are coated to have about a 1.0 mm width on areas corresponding to the side edge portions 12c and 12d (22c and 22d) on the front and rear sides in the sealing portion formation areas A1 and A2 of the first transparent glass substrate 12 of the first electrode substrate 10 and the second transparent glass substrate 22 of the second electrode substrate 20, respectively. As shown in FIG. 6, corresponding sealants 32 are bonded such that the first and second transparent glass substrates 12 and 22 are maintained so as to be separated by a certain distance (for example, about 40 nm). The distance may be predetermined. Then, an ultraviolet light L1 is irradiated onto the sealant 32 from above the first and second transparent glass substrates 12 and 22 so as to cure the sealant 32, so that the side edge portions 12c and 12d (22c and 22d) on the front and rear sides of the first and second transparent glass substrates 12 and 22 are tightly sealed.

On the other hand, the laser sealing portion 30b is generated as follows. As shown in FIG. 7, sealing glass base materials 34 which have a width of about 0.5 mm and which are made of the same material as the first and second transparent glass substrates 12 and 22 are interposed between areas corresponding to the side edge portions 12a and 12b (22a and 22b) on the right and left sides in the sealing portion formation areas A1 and A2 of the first and second transparent glass substrates 12 and 22. A laser light L2 is irradiated onto the sealing glass base material 34 from above the first transparent glass substrate 12 so as to melt the sealing glass base material 34, so that the sealing glass base material 34 is welded to the first and second transparent glass substrates 12 and 22. Thus, the side edge portions 12c and 12d (22c and 22d) on the front and rear sides of the first and second transparent glass substrates 12 and 22 are tightly sealed. It is advantageous that the laser light L2 has a transmission factor of about 50% or more with respect to the transparent glass substrate 12 (22). For example, a gallium-arsenic-based semiconductor laser, a gallium-arsenic-aluminum-based semiconductor laser, or a YAG laser, etc. may be used.

In addition, in a laser welding process, when laser light absorbing materials 35 such as a carbon black, a magic ink, or a printer toner are interposed in the interfaces between the sealing glass base material 34 and the first and second transparent glass substrates 12 and 22, the laser light absorbing materials 35 absorb the irradiated laser light, so that the sealing glass base materials 34 are instantly melted and welded to the first and second transparent glass substrates 12 and 22. For this reason, in order to prevent the semiconductor layer 16 or the catalyst conductive layer 26 from being affected by heat caused by the laser welding, it is advantageous that a laser light absorbing layer such as a carbon black be provided at contact surfaces between the first and second transparent glass substrates 12 and 22 and the sealing glass base materials 34. The carbon black or other such material may be provided using, for example, a printing process or a sintering process.

Further, as shown in FIGS. 4 and 5, end portions 34a of the sealing glass base materials 34 are formed as a circular arc as viewed from a horizontal section. Thus, an area (i.e., a length of the bonded interface 30c in a horizontal direction) of a bonded interface 30c between the sealant sealing portion 30a which has a width of 1.0 mm and the laser sealing portion 30b which has a width of 0.5 mm is increased. Accordingly, the electrolyte 18 is more easily trapped within the sealed portion such that the electrolyte does not leak out as easily through the bonded interface 30c between the sealant sealing portion 30a and the laser sealing portion 30b.

Next, a method of manufacturing the dye-sensitized solar cell 1 will be described.

The first electrode substrate 10 and the second electrode substrate 20 are prepared in advance. That is, the first electrode substrate 10 is made such that the transparent conductive film 14 and the porous oxide semiconductor layer 16, which is impregnated with a sensitizing dye, are integrally laminated on the first transparent glass substrate 12, and the second electrode substrate 20 is made such that the conductive metal thin film 24 and the catalyst conductive layer 26 are integrally laminated on the second transparent glass substrate 22. Before the first electrode substrate 10 is integrally sealed with the peripheral portion of the second electrode substrate 20, the sealing glass base material 34 is placed on the second transparent glass substrate 22 of the second electrode substrate 20 which is horizontally disposed, and the sealant 32 is coated on the first and second transparent glass substrates 12 and 22, respectively. When the first electrode substrate 10 (first transparent glass substrate 12) is placed on the second electrode substrate 20 (second transparent glass substrate 22), the sealant 32 and the sealing glass base material 34 which are disposed so as to be extended along the peripheral portion of the first and second transparent glass substrates 12 and 22 so as to surround the porous oxide semiconductor layer 16 and the catalyst conductive layer 26.

In this state, the laser light L2 is irradiated onto the sealing glass base material 34 from above the first transparent glass substrate 12 (refer to FIG. 7), so that the side edge portions 12c and 12d (22c and 22d) on the front and rear sides of the first and second transparent glass substrates 12 and 22 are tightly sealed (glass welding) by the laser sealing portion 30b. Further, the ultraviolet light L1 is irradiated onto the sealant 32 from above the first and second transparent glass substrates 12 and 22 (refer to FIG. 6), so that the side edge portions 12c and 12d (22c and 22d) on the front and rear sides of the first and second transparent glass substrates 12 and 22 are tightly sealed by the sealant sealing portion 30a. Finally, the electrolyte 18 is injected into the sealed space S through the injection hole, and the injection hole 19a is closed with the stopper 19b, and thus the solar cell 1 is completed. The irradiation of the laser light L2 onto the sealing glass base material 34 and the irradiation of the ultraviolet light L1 onto the sealant 32 may alternatively be simultaneously performed.

The above-mentioned solar cell 1 of the first exemplary embodiment has operations and advantages as follows.

In the dye-sensitized solar cell according the first exemplary embodiment of the present invention, as compared with the related art in which an entire sealing area along a peripheral portion of tabular base materials facing each other is sealed with a sealant, a part of the sealing area is made so as to be sealed by performing laser welding on the sealing glass base material 34 which is interposed thereto, so that it is more difficult for the electrolyte to leak out from the sealing portion 30. That is, since there is no bonded interface between the sealing glass base materials 34 and the first and second transparent glass substrates 12 and 22, the electrolyte (for example, including one which is gasified) leaks out less from the laser sealing portions 30b.

In addition, the bonded interface 30c between the sealant sealing portion 30a and the laser sealing portion 30b is formed as in a circular arc as viewed from a horizontal section, so that a length of the bonded interface 30c in a horizontal direction of the contact surface 30c with respect to the laser sealing portion 30b is increased. Thus, the electrolyte 18 does not leak out as easily from the contact surface 30c between the sealant sealing portion 30a and the laser sealing portion 30b.

Additionally, among the sealing areas which are disposed so as to be extended in a strip shape along the peripheral portion of the first and second transparent glass substrates 12 and 22, a sealing area which is overlapped with the conductive films 14 and 24 and in which a part of the conductive films 14 and 24 which form the electrodes is less likely to be damaged since this area is sealed by the sealant 32. Thus, the function of the electrodes (i.e., the conductive films 14 and 24) as the power feeding path is less likely to be damaged (for example, by disconnection).

Moreover, since the electrolyte is less likely to leak out from the laser sealing portion 30b, a laser welding width (i.e., a width of the laser sealing portion 30b) can be made more narrow, and thus it is possible to increase the area of the semiconductor layer 16 and the catalyst conductive layer 26 (i.e., an effective power generating area of the solar cell 1) with respect to the area of the first electrode substrate 10 and the second electrode substrate 20.

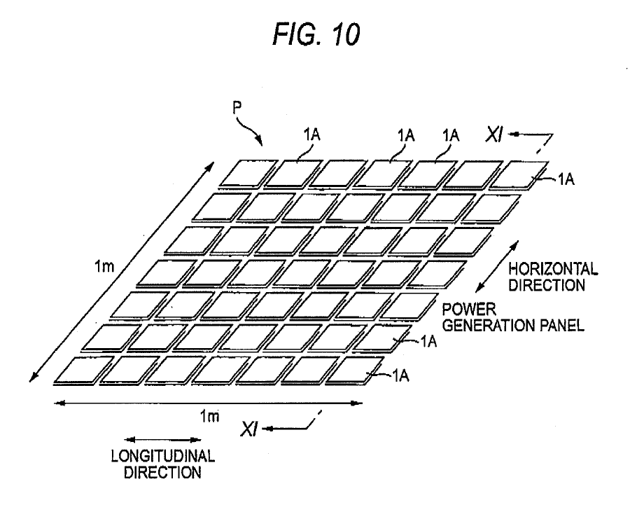

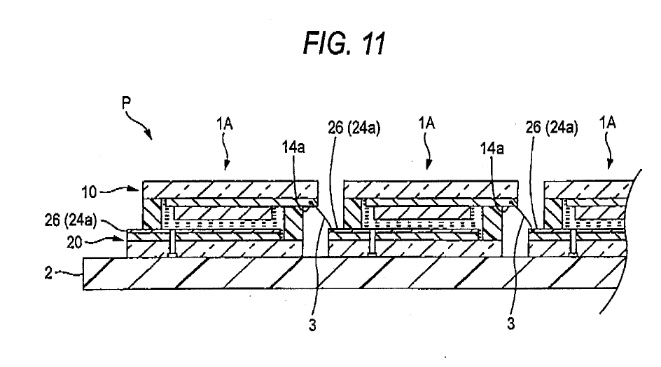

Additionally, the sealing glass base materials 34 which are melted by the laser irradiation are integrally welded to contact surfaces with the first and second transparent glass substrates 12 and 22, respectively, so that the laser sealing portion 30b does not protrude to the outside of the first and second transparent glass substrates 12 and 22. Accordingly, when the dye-sensitized solar cells are arranged into a solar power panel, adjacent cells can be disposed more closely to each other and a number of cells which can be disposed in a given area may be increased. Accordingly, a total electric generating capacity of the solar power panel may be increased. That is, as shown in FIGS. 10 and 11, solar power panel P comprises a plurality of the solar cells. The solar cells are arranged such that a number of rectangular solar cells 1A are lengthwise and crosswise disposed on a square plate 2. The square plate 2 may have dimensions such as about 1 m on each side. Thus, the solar cells are arranged close to one another in a grid shape. In the example shown in FIG. 10, there are seven cells 1A whose side edge portions (laser sealing portions 30b) where the laser welding is performed are disposed closer to each other in a backward or forward direction (horizontal direction in FIG. 10), and the seven cells 1A are also disposed closer to each other in a horizontal direction of the panel (i.e., a direction perpendicular to a backward or forward direction of the panel). Thus, 49 cells in total are disposed in a grid shape.

As shown in FIG. 11, between the adjacent cells 1A and 1A in a horizontal direction of the panel, a conductive film 24a (catalyst conductive layer 26) which is upwardly exposed from the second electrode substrate 20 of one cell 1A is connected to the conductive film 14a which is downwardly exposed from the first electrode substrate 10 of the adjacent cell 1A using a lead line 3. Thus, the 49 cells 1A are coupled together in series. Since the laser sealing portion 30b does not protrude in the side edge portion at which each cell 1A is preformed with the laser welding, cells which are adjacent in a backward or forward direction are disposed closer to each other, so that 49 cells 1A can be disposed in the solar power panel of side 1 m. Therefore, the total electric generating capacity of the solar power panel P is increased.

### Second and Third Exemplary Embodiments

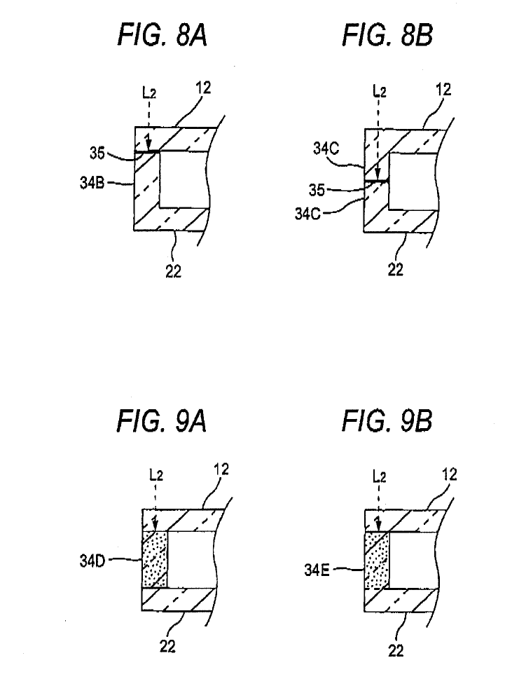

FIGS. 8A and 8B are cross-sectional views illustrating a portion of a dye-sensitized solar cell according to a second exemplary embodiment and a third exemplary embodiment of the invention, respectively.

In the above-mentioned first exemplary embodiment, the sealing glass base material 34 is formed separate from the first and second transparent glass substrates 12 and 22. However, as shown in FIGS. 8A and 8B in terms of the second and third exemplary embodiments of the invention, respectively, the sealing glass base materials 34B and 34C may be formed so as to be integrated with the first and second transparent glass substrates 12 and 22.

That is, FIG. 8A is a view illustrating an example of a sealing glass base material 34B which is formed as a part of a second transparent glass substrate 22, and FIG. 8B is a view illustrating an example of a sealing glass base materials 34C and 34C which are formed as a part of the first and second transparent glass substrates 12 and 22, respectively. The laser light absorbing material 35 is interposed between the sealing glass base material 34B and the first transparent glass substrate 12 in the case of the second exemplary embodiment, or between the sealing glass base materials 34C and 34C in the case of the third exemplary embodiment, and laser welding is performed.

In the second and third exemplary embodiments, since a separate material in addition to the first and second transparent glass substrates 12 and 22 is not used for the sealing glass base material, a configuration is simplified.

In addition, in the above-mentioned first exemplary embodiment, the laser welding process is used to weld the sealing glass base material 34 to the first and second transparent glass substrates 12 and 22 in two places. However, in the second and third exemplary embodiments, since laser welding is applied in just one place, the welding process is more easily performed.

### Fourth and Fifth Exemplary Embodiments

In the above-mentioned first to third exemplary embodiments, laser light absorbing materials 35 are interposed between the sealing glass base materials and the first and second transparent glass substrates 12 and 22, and the sealing glass base materials on which the laser light is irradiated are instantly welded in the positions of the laser light absorbing materials 35. However, according to fourth and fifth exemplary embodiments of the present invention as shown in FIGS. 9A and 9B, respectively, the laser light absorbing material may be dispersed in the sealing glass base materials 34D and 34E, respectively.

That is, in the fourth exemplary embodiment shown in FIG. 9A, a sealing glass base material 34D in which the laser light absorbing material is dispersed is made of a separate material from the first and second transparent glass substrates 12 and 22. In the fifth exemplary embodiment shown in FIG. 9B, a sealing glass base material 34E in which the laser light absorbing material is dispersed is formed integrally with the second transparent glass substrate 22 (i.e., on a part of the second transparent glass substrate 22). Thus, in the fourth and fifth exemplary embodiments, as in the case of the second and third exemplary embodiments, since laser welding is performed in just one place, the welding process is more easily performed.

Further, in the above exemplary embodiments, both the first transparent glass substrate 12 and the second transparent glass substrate 22 are made of a transparent glass plate. However, in addition to the glass plate, a transparent synthetic resin, such as a polyethylene terephthalate (PET) resin, or a polyethylene naphthalate (PEN) resin, or a polycarbonate (PC) resin, may alternatively be used.

In addition, when the first transparent glass substrate 12 and the second transparent glass substrate 22 are made of a transparent synthetic resin substrate, it is advantageous that the sealant 32 be one suitable for sealing the resin, and it is also advantageous that the sealing base material 34 be made of the same material as that of the first and second transparent glass substrates and be one suitable for performing laser welding on the resin.

In addition, as the transparent films 14 and 24, other transparent oxide semiconductors, such as an indium tin oxide (ITO) or a tin oxide (SnO₂), or a plurality of these materials may be used instead of the fluoridated tin oxide (FTO).

In addition, as the porous oxide semiconductor layer 16, a single of two or more kinds of a tin oxide (SnO₂), a tungsten oxide (WO₃), a zinc oxide (ZnO), a niobium oxide (Nb₂O₅) may alternatively be used instead of the titanium dioxide (TiO₂). As the sensitizing dye held in the porous oxide semiconductor layer 16, beginning with a ruthenium complex in which a bipyridine structure, a terpyridine structure or the like is included in a ligand, and an alloy complex such as porphyrin and phthalocyanine, an organic dye such as eosin, rhodamine, and merocyanine may be used.

According to illustrative aspects of the present invention, a dye-sensitized solar cell is provided which includes both an area in which the conductive film is overlapped with a sealing area which is disposed so as to be extended in a strip shape along the peripheral portion of the base materials that is sealed by using a sealant which is interposed therebetween, and an area in which the conductive film is not overlapped that is sealed by performing a laser welding on the sealing base material interposed therebetween.

According to one or more illustrative aspects of the invention, there is provided a dye-sensitized solar cell including a first tabular transparent base material which is formed by laminating a transparent conductive film as a first electrode and an oxide semiconductor layer which is impregnated with a sensitizing dye; a second tabular base material which is formed by laminating a conductive film as a second electrode and a catalyst conductive layer, the second tabular base material being disposed to face the first tabular transparent base material such that the oxide semiconductor layer opposes the catalyst conductive layer; and an electrolyte which is sealed in a sealed space which is interposed between the first and second electrodes and is defined by tightly sealing a peripheral portion between the first and second tabular base materials, wherein at least an area where the conductive film is overlapped with the sealing area which is disposed so as to be extended in a strip shape along the peripheral portion of tile first and second tabular base materials is tightly sealed by a sealant which is interposed between the first and second tabular base materials, and an area where the conductive film is not overlapped with the sealing area is tightly sealed by performing laser welding on a sealing base material which is made of the same material as that of the first and second tabular base materials and interposed between the first and second tabular base materials.

According to the one or more illustrative aspects, since a part of the sealing area is tightly sealed by performing the laser welding on the interposed sealing base material, it is less easy for an electrolyte to leak out through a sealing portion by that much. That is, since there is no bonded interface between the sealing base material and the first and second tabular base materials in the laser welding portion between the sealing base material and the first and second tabular base materials, the electrolyte (for example, including one which is gasified) does not leak out as easily from the sealing portion where the laser welding is performed.

In addition, among the sealing areas which are disposed so as to be extended in a strip shape along the first and second tabular base materials, a sealing area which is overlapped with the conductive film is less likely to be damaged when the laser welding is performed, so that the function of the electrodes (conductive films) as the power feeding path is less likely to be damaged (for example, by disconnection).

In addition, since the laser welding area prevents the electrolyte from leaking out, a width of the laser sealing portion can be made more narrow, and thus it is possible to increase an area of the oxide semiconductor layer and the catalyst conductive layer (i.e., an effective power generating area of the solar cell) with respect to an area of the tabular substrate.

In addition, the sealing base material which is melted by a laser irradiation is integrally welded in an interface between the first and second tabular base materials, respectively, so that the sealing base material does not protrude to the outside of the first and second tabular base materials, so that it is less likely that the laser sealing portion protrudes to the outside of the tabular base materials. For this reason, in a solar power panel where a number of solar cells are disposed closely, adjacent cells can be disposed more closely to each other and a number of cells which can be disposed in a given area is increased, so that a total electric generating capacity of the solar power panel is increased.

According to one or more illustrative aspects of the present invention, the first tabular transparent base material and the second tabular base material may be formed as a rectangular shape, and side edge portions on either right and left sides or front and rear sides of the first and second tabular base materials may be sealed by laser welding.

When the solar cell is provided as a solar power panel in which a number of rectangular solar cells are lengthwise and crosswise disposed closely to one another in a grid shape, since the laser sealing portion in each cell does not protrude to the outside of the side edge portion where the laser welding is performed, the side edge portions (the side edge portions where the conductive films are not interposed) of the adjacent cells where the laser welding is performed can be disposed more closely to each other, so that a number of cells that can be disposed is increased.

According to one or more illustrative aspects of the present invention, the sealing base material may be formed integrally with at least one of the first and second tabular base materials. In other words, the sealing base material may be formed on a part of at least one of the first tabular base material and the second tabular base material.

Since a part of at least one of the first tabular base material and the second tabular base material also serves as the sealing base material, a separate material is not used in addition to the first and second tabular base materials.

In addition, since the sealing base material is integrally formed on at least one of the first and second tabular base materials (i.e., when a part of at least one of the first and second tabular base materials serves as the sealing member), the laser welding may be performed on only one of the first and second tabular base materials (i.e., laser welding may be preformed in only one place).

According to one or more illustrative aspects of the present invention, laser light absorbing materials may be interposed at interfaces between the sealing base material and the first and second tabular base materials, or a laser light absorbing material may be dispersed in the sealing base material.

Since the irradiated laser light is absorbed by the laser light absorbing material, and the sealing base material is efficiently melted and welded to the first and second tabular base materials, the effect of heat caused by the laser welding on the oxide semiconductor layer or the catalyst conductive layer is decreased.

According to one or more illustrative aspects of the present invention, it is easier to prevent the electrolyte from leaking out of the dye-sensitized solar cell more than compared with the related art structure. Further, since the sealing areas where the conductive film may be more easily damaged when laser welding is performed are tightly sealed by the sealant, the electrodes (conductive films) as the power feeding, path are less likely to be damaged.

In addition, since there is no fear that the electrolyte leaks out from the sealing portion where the laser welding is performed even though the electrolyte is gasified, it is possible to increase an area (an effective power generating area of the solar cell) of the oxide semiconductor layer and the catalyst conductive layer with respect to an area of the tabular base materials by reducing a width of the sealing portion where the laser welding is performed. Thus, an electric generating capacity of the solar cell can be increased.

In addition, in the sealing portion where the laser welding is performed, the sealing base material does not protrude to the outside of the first and second tabular base materials. Therefore, in a solar power panel where a number of solar cells are disposed, the adjacent cells may be disposed more closely to each other, and the number of cells which can be disposed in a given area may be increased, and the total electric generating capacity of the solar power panel can be increased.

While the present invention has been shown and described with reference to certain exemplary embodiments thereof other implementations are within the scope of the claims. It will be understood by those skilled in the art that various changes in form and details may be made therein without departing from the spirit and scope of the invention as defined by the appended claims.

What is claimed is:

1. A dye-sensitized solar cell comprising:
a first electrode substrate comprising:
a first tabular substrate which is transparent;
a transparent conductive film formed on the first tabular substrate; and
an oxide semiconductor layer which is formed on the transparent conductive film and which is impregnated with a sensitizing dye;
a second electrode substrate comprising:
a second tabular substrate;
a conductive film formed on the second tabular substrate; and
a catalyst conductive layer formed on the conductive film,
the second electrode substrate being disposed to face the first electrode substrate such that the oxide semiconductor layer opposes the catalyst conductive layer;
a sealing member that seals a peripheral area between the first electrode substrate and the second electrode substrate, the sealing member comprising:
a sealant provided at least in a first area of the peripheral area that overlaps with the transparent conductive film or the conductive film; and
a sealing base material provided in a second area of the peripheral area that does not overlap with the transparent conductive film or the conductive film, the sealing base material being made of a same material as a material of the first tabular substrate or the second tabular substrate; and
an electrolyte which is filled in a sealing space formed by the first electrode substrate, the second electrode substrate and the sealing member.

2. The dye-sensitized solar cell according to claim 1, wherein the first tabular substrate and the second tabular substrate are each formed in a rectangular shape, and
wherein at least one side edge portion of the first tabular substrate and the second tabular substrates is provided with the sealing base material.

3. The dye-sensitized solar cell according to claim 1, wherein the sealing base material is formed integrally with at least one of the first tabular substrate and the second tabular substrate.

4. The dye-sensitized solar cell according to claim 1, further comprising a laser light absorbing material that is interposed between the sealing base material and the first tabular substrate and between the sealing base material and the second tabular substrate.

5. The dye-sensitized solar cell according to claim 1, further comprising a laser light absorbing material that is dispersed in the sealing base material.
